(19) United States
(12) Patent Application Publication
(10) Pub. No.: US 2016/0221017 A1
(43) Pub. Date: Aug. 4, 2016

(54) EVAPORATION MASK AND METHOD FOR MANUFACTURING EVAPORATION MASK

(71) Applicant: HON HAI PRECISION INDUSTRY CO., LTD., New Taipei (TW)

(72) Inventor: CHUN-CHIEH HUANG, New Taipei (TW)

(21) Appl. No.: 14/821,030

(22) Filed: Aug. 7, 2015

(30) Foreign Application Priority Data
Feb. 2, 2015 (TW) 104103483

(51) Int. Cl. B05B 15/04; B23K 26/38; B29C 43/52; G03F 7/40; B29C 43/02

(52) U.S. Cl. CPC B05B 15/045; G03F 7/40; B29C 43/02; B29C 43/52; B23K 26/38; B29L 2007/002

(57) ABSTRACT

An evaporation mask for vapor deposition to form pixels on a display substrate is disclosed. The evaporation mask includes a main body made of resin. The main body has a shape of a thin plate. A plurality of magnetic particles is dispersed in the main body. A plurality of apertures is defined through the main body to define a pixel pattern. A rectangular base defines a central rectangular opening. The main body is secured to a top face of the base to cover the opening thereof. The apertures of the main body communicate with the opening of the base.

### CROSS-REFERENCE TO RELATED APPLICATIONS

This application claims priority to Taiwan Patent Application No. 104103483 filed on Feb. 2, 2015, the contents of which are incorporated by reference herein.

### FIELD

The subject matter herein generally relates to an evaporation mask for depositing a thin film on a substrate wherein the evaporation mask has a nonmetallic film dispersed with magnetic particles; the subject matter herein also relates to a method for manufacturing the evaporation mask.

### BACKGROUND

An organic electroluminescent display panel is made by evaporating organic electroluminescent material on a substrate through an evaporation mask. The evaporation mask is made of metal. During the vapor deposition, the evaporation mask is tightly attached to the substrate by using a magnet which attracts the evaporation mask onto the substrate. The evaporation mask is completely made of metal which is difficult to form a masking pattern thereon. Furthermore, the metal has a thermal expansion coefficient quite different from a thermal expansion coefficient of the substrate.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a perspective view of an evaporation mask in accordance with a first embodiment of the present disclosure.

FIG. 2 is a cross-sectional view the evaporation mask of FIG. 1, taken along line thereof

FIG. 3 is a flowchart of a method for manufacturing the evaporation mask of FIG. 1.

FIG. 4 is a perspective view showing mixing magnetic particles and resin particles together to form a main body.

FIG. 5 is a perspective view showing a hollow base.

FIG. 6 is a perspective view showing the main body adhered to the base.

FIG. 7 is a perspective view showing that a plurality of apertures is to be formed in the main body.

FIG. 8 is a perspective view of an evaporation mask in accordance with a second embodiment of the present disclosure.

FIG. 9 is a cross-sectional view of the evaporation mask of FIG. 8, taken along line IX-IX thereof

FIG. 10 is a flowchart of a method for manufacturing the evaporation mask of FIG. 8.

FIG. 11 is a perspective view showing mixing magnetic particles and resin particles together to form a main body.

FIG. 12 is a perspective view showing a hollow base.

FIG. 13 is a perspective view showing the main body adhered to the base.

FIG. 14 is a perspective view showing that a plurality of groups of apertures is to be formed in the main body.

FIG. 15 is a perspective view of an evaporation mask in accordance with a third embodiment of the present disclosure.

FIG. 16 is a cross-sectional view of the evaporation mask of FIG. 15, taken along line XVI-XVI thereof

FIG. 17 is a flowchart of a method for manufacturing the evaporation mask of FIG. 15.

FIG. 18 is a perspective view showing mixing magnetic particles and resin particles together to form a main body

FIG. 19 is a perspective view showing the main body adhered to a plate.

FIG. 20 is a perspective view showing a photoresist coating applied to a bottom face of the plate.

FIG. 21 is a perspective view showing the photoresist coating being subjected to a Hat irradiation through a photo mask.

FIG. 22 is a perspective view showing that the photoresist coating becomes a patterned coating.

FIG. 23 is a perspective view showing a middle plate defining a plurality of holes therethrough.

FIG. 24 is a perspective view showing that the middle plate is to be mounted to a hollow base.

FIG. 25 is a perspective view showing that a plurality of groups of apertures is to be formed in the main body.

FIG. 26 is a flowchart of a method for using the evaporation mask in accordance with the present disclosure to carry out vapor deposition.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

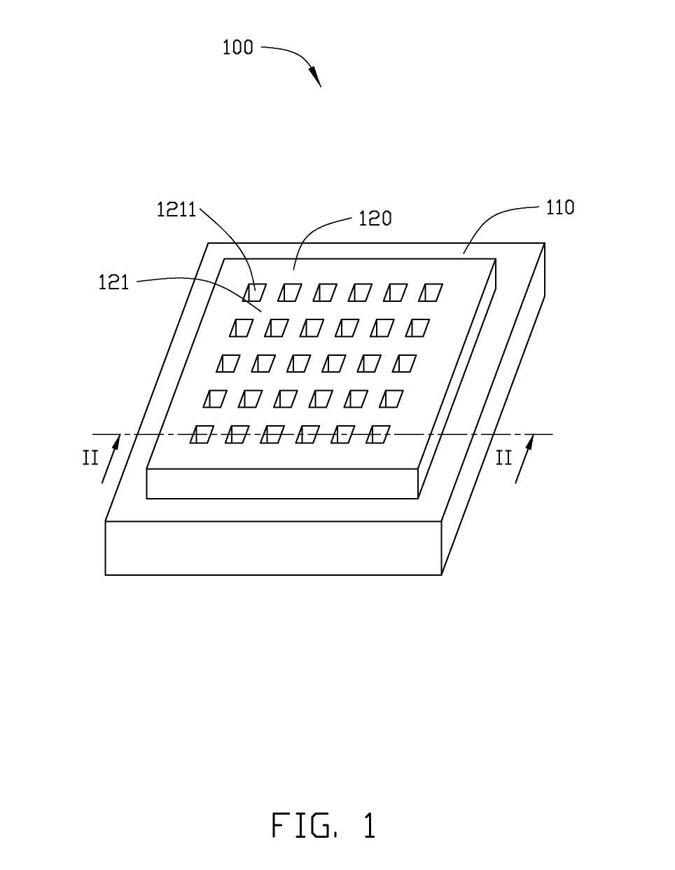

Referring to FIG. 1, a first embodiment of the present disclosure is described in relation to an evaporation mask 100 for use in carrying out a vapor deposition on a display substrate (not shown) so that the display substrate can have organic electroluminescent material thereon to thereby function as a component of a display panel. The evaporation mask 100 has a base 110 and a main body 120 coupled to a center of the base 110. Each of the base 110 and the main body 120 has a substantially rectangular shape. The base 110 has a frame-like configuration. The main body 120 has a thin plate-like configuration and defines a plurality of square apertures 1211 therethrough to thereby form a pixel pattern 121 which is used for vapor deposition of a patterned film on the display substrate to form a plurality of organic pixels on the display substrate. The apertures 1211 are arranged in a rectangular array.

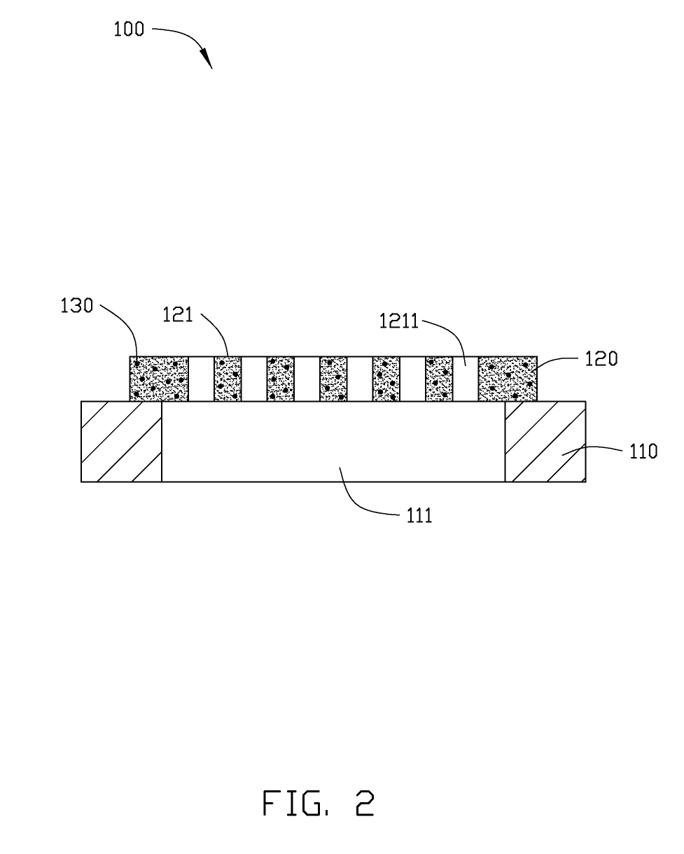

Referring to FIG. 2, the base 110 defines an opening 111 in a middle thereof. The main body 120 is mounted on the base 110 and covers the opening 111. The apertures 1121 extend through the main body 120 to communicate with the opening 111. The main body 120 has a plurality of magnetic particles 130 evenly dispersed therein. In an alternative embodiment, the base 110 can be omitted; the evaporation mask 100 only requires the main body 120 dispersed with the magnetic particles 130. The apertures 1121 can be formed by laser processing or etch processing to the main body 120.

The base 110 can be made of class or magnetic metal. In this embodiment, the base 110 is made of Invar, generally known as FeNi36 or 64FeNi which is a nickel-iron alloy notable for its low coefficient of thermal expansion. The main body 120 which is dispersed with the magnetic particles 130 can be coupled to the base 110 by gluing the main body 120 to the base 110. The magnetic particles 130 can be attracted to the base 110 when the base 110 is made of magnetic metal thereby to enhance the coupling strength between the base 110 and the main body 120.

The main body 120 can be made of resin material such as polyimide (PI), polyethylene naphthalate (PEN), polyethylene terephthalate (PET), or polysulfone (PSU). In this embodiment, the main body 120 is made of polyimide resin. The apertures 1211 each can have a shape of a square, a rectangle, a circle or an ellipse or any other regular or irregular shape. In this embodiment, the aperture 1211 has a shape of a square.

The magnetic particles 130 each can be a round sphere, an elliptical sphere or an irregular sphere. In this embodiment, the magnetic particle 130 is a round sphere having a diameter smaller than 1 μm. When the mametic particle 130 is an elliptical or irregular sphere, the largest dimension of the magnetic particle 130 is not larger than 1 μm. The magnetic particles 130 can be made of magnetic material, paramagnetic material or antimagnetic material. In this embodiment, the magnetic particles 130 can be made of ferromagnetic material such as iron, cobalt, nickel or an alloy thereof, or ferric oxide such as Fe₂O₃ or Fe₃O₄. In this embodiment, the magnetic particles 130 are made Fe₂O₃.

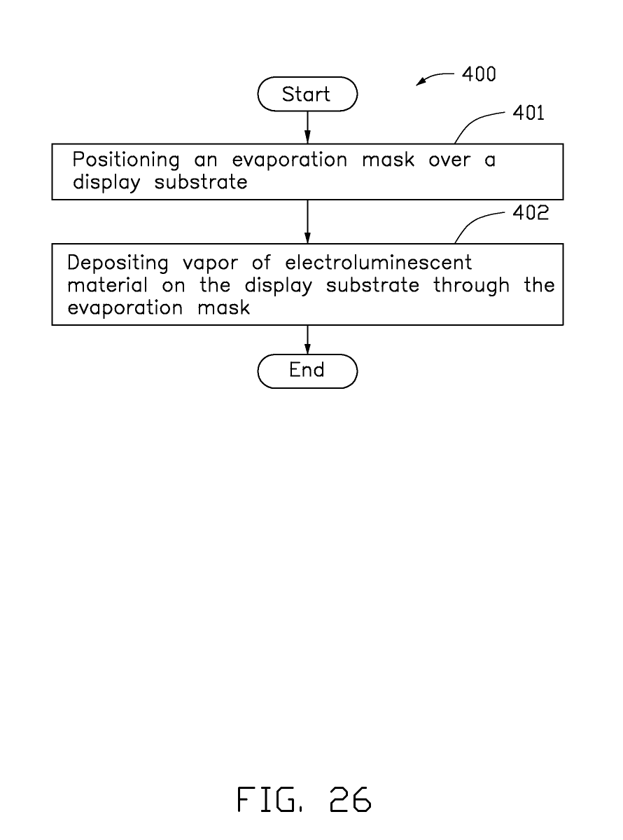

Referring to FIG. 26, a method 400 of using the evaporation mask 100 is disclosed. A flowchart is presented in accordance with an example embodiment. The example method 400 is provided by way of example, as there are a variety of ways to carry out the method. The method 400 described below can be carried out using the configurations illustrated in FIGS. 1 and 2, for example, and various elements of these figures are referenced in explaining example method 400. Each block shown in FIG. 26 represents one or more processes, methods or subroutines, carried out in the example method 400. Furthermore, the illustrated order of blocks is illustrative only and the order of the blocks can change according to the present disclosure. Additional blocks can be added or fewer blocks may be utilized, without departing from this disclosure. The example method 400 can begin at block 401.

At block 401, the evaporation mask 100 is brought to be located over and fixed to an upper top of a display substrate (not shown). To achieve this, a magnetic plate is brought to be located over an underside of the display substrate. By the attraction of the magnetic plate to the magnetic particles 130 dispersed in the main body 120, the main body 120 can be mametically pulled to the upper face of the display substrate. It can be understood that when the base 110 is made magnetic metal, the base 110 is also magnetically pulled to the upper face of the display substrate.

At block 402, organic electroluminescent material is evaporated to become vapor. The vapor flows through the apertures 1211 to be deposited on the upper face of the display substrate to thereby form organic pixels thereon.

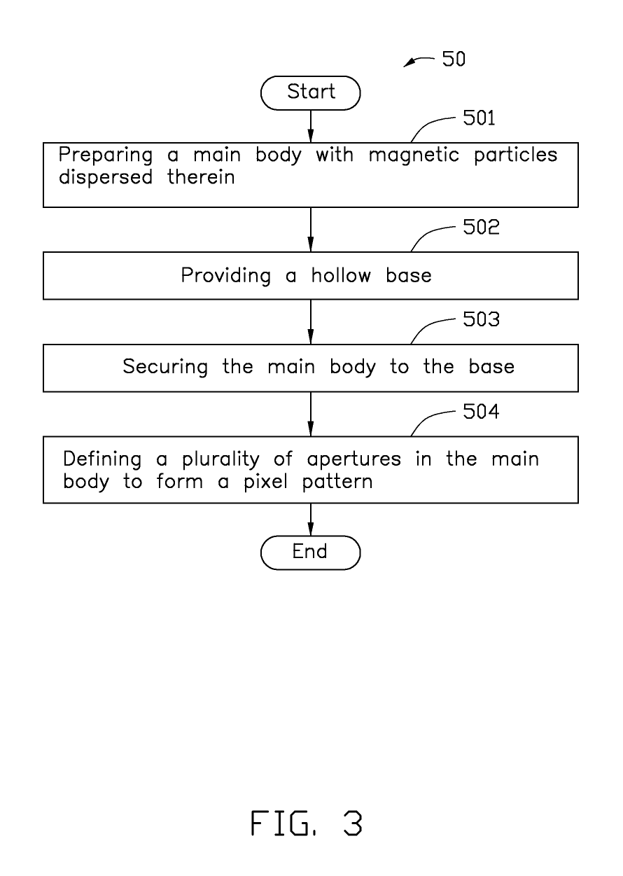

Referring to FIG. 3, a flowchart is presented in accordance with an example embodiment. The example method 50 is provided by way of example, as there are a variety of ways to carry out the method. The method 50 described below can be carried out to manufacture the evaporation mask 100 illustrated in FIGS. 1 and 2. Each block shown in FIG. 3 represents one or more processes, methods or subroutines, carried out in the example method 50. Furthermore, the illustrated order of blocks is illustrative only and the order of the blocks can change according to the present disclosure. Additional blocks can be added or fewer blocks may be utilized, without departing from this disclosure. The example method 50 can begin at block 501.

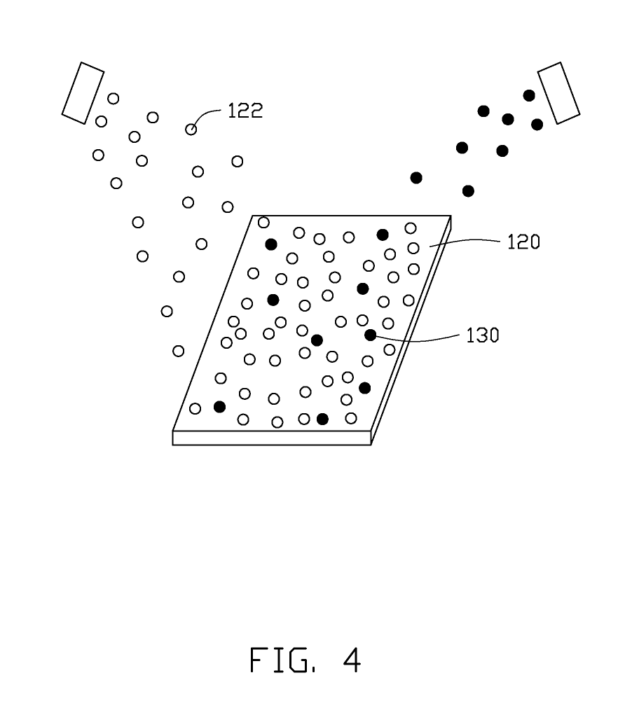

At block 501, also referring to FIG. 4, magnetic particles 130 and resin particles 122 are mixed together and then heat pressed to form the main body 120. In this embodiment, the resin particles 122 are polyimide resin particles.

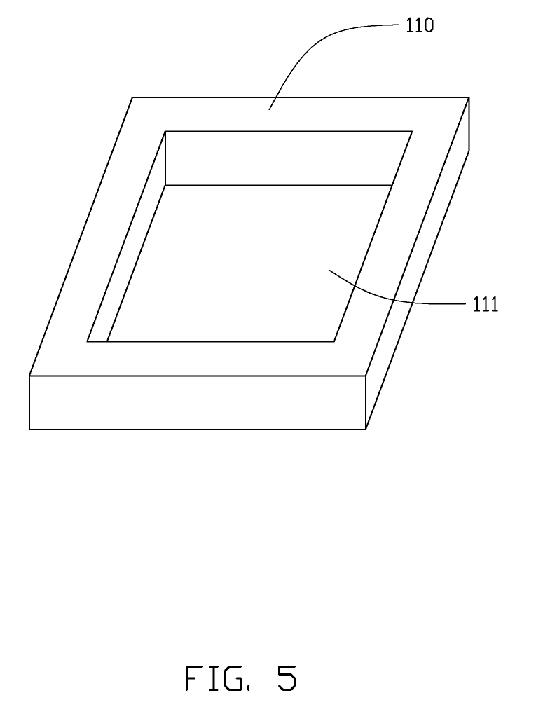

At block 502, also referring to FIG. 5, the base 110 is provided which is a hollow rectangle defining the central rectangular opening 111 whereby the base 110 has a configuration of a rectangular frame.

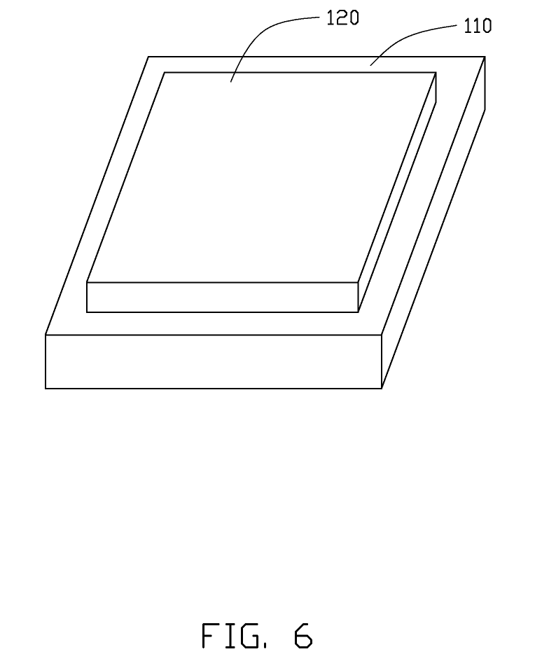

At block 503, also referring to FIG. 6, the main body 120 is adhered to a center of a top face of the base 110 around the opening 111 to cover the opening 111 of the base 110.

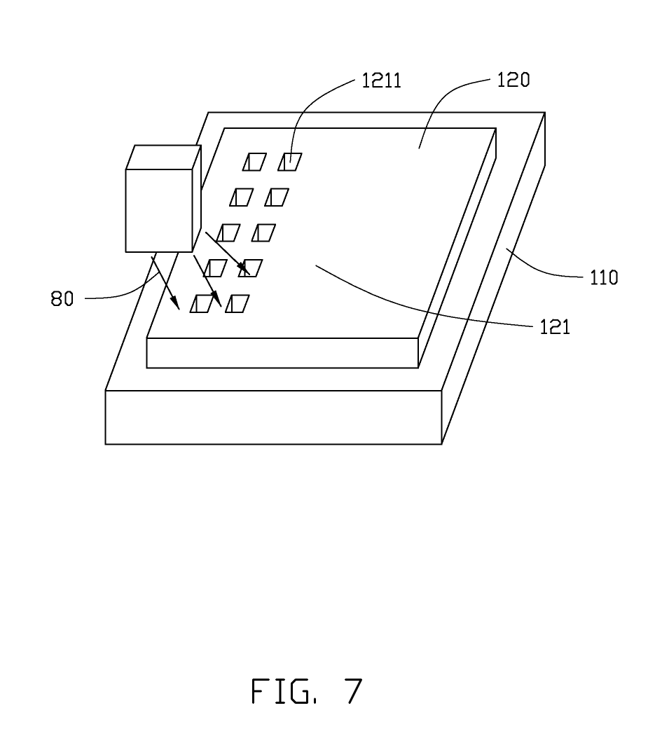

At block 504, also referring to FIG. 7, the main body 120 is processed to form the pixel pattern 121 by using laser beams 80 to form the plurality of apertures 1211 in the main body 120. Accordingly the evaporation mask 100 in accordance with the first embodiment of the present disclosure is obtained. An area of the pixel pattern 121 is substantially the same as an area of the opening 111.

In an alternative embodiment where the base 110 is not necessary and only the main body 120 dispersed with the magnetic particles 130 is required, then blocks 502 and 503 can be omitted.

In the present disclosure, since the main body 120 is made of resin which has a coefficient of expansion (i.e., 3.9 μm/m° C.) similar to a coefficient of expansion (i.e., 3.39 μm/m° C.) of the display substrate for forming a display screen of a computer or mobile phone, during vapor deposition, a relative movement due to thermal expansions of the evaporation mask 100 and the display substrate can be minimized. Furthermore, since the main body 120 is dispersed with the magnetic particles 130 which can be attracted by the magnetic plate located on the underside of the display substrate, an accurate position of the pixel pattern relative to the display substrate can be further assured. Moreover, according to the present disclosure, since the main body 120 is made of resin, the processing of the main body 120 by the laser beams 80 to define the apertures 1211 to thereby form the pixel pattern 121 is relatively easy and time and cost saving. In addition, the precision of dimensions and positions of the apertures 1211 can be enhanced by the laser processing in accordance with the present disclosure.

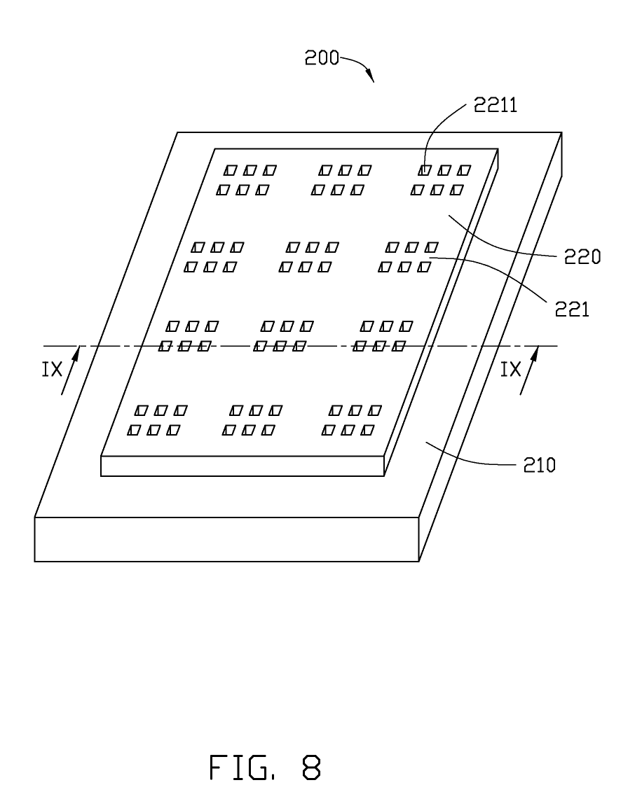

Referring to FIG. 8, an evaporation mask 200 in accordance with a second embodiment of the present disclosure is shown. The evaporation mask 200, like the evaporation mask 100 of the first embodiment, also has a base 210 and a main body 220 located over a top face of the base 210. The main body 220 defines a plurality of groups of apertures 2211 to define a plurality of pixel patterns 221 each including a corresponding group of apertures 2211. Each of the base 210 and the main body 220 has a substantially rectangular shape. Each of the groups of apertures 2211 is a rectangular array.

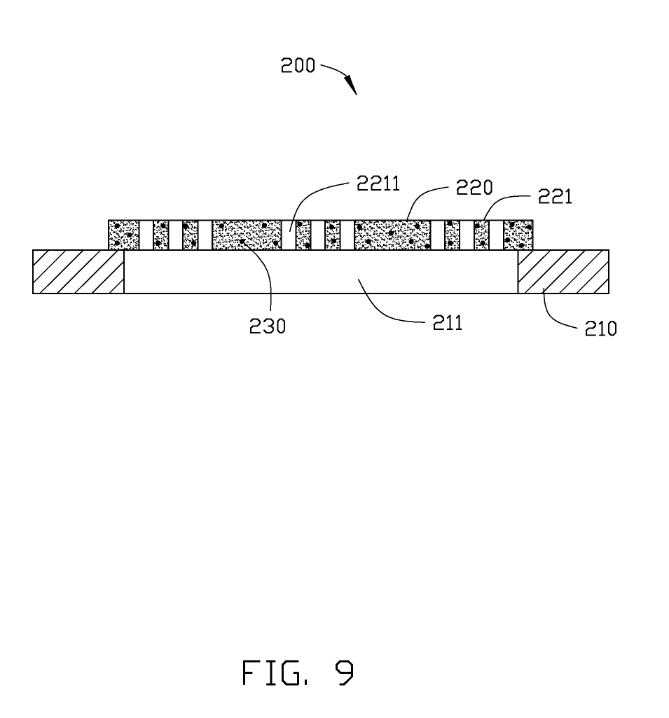

Referring to FIG. 9, the base 210 defines a rectangular opening 211 in a center thereof. The main body 220 is dispersed with magnetic particles 230 and located over the rectangular opening 211. The apertures 2211 are all in communication with the opening 211.

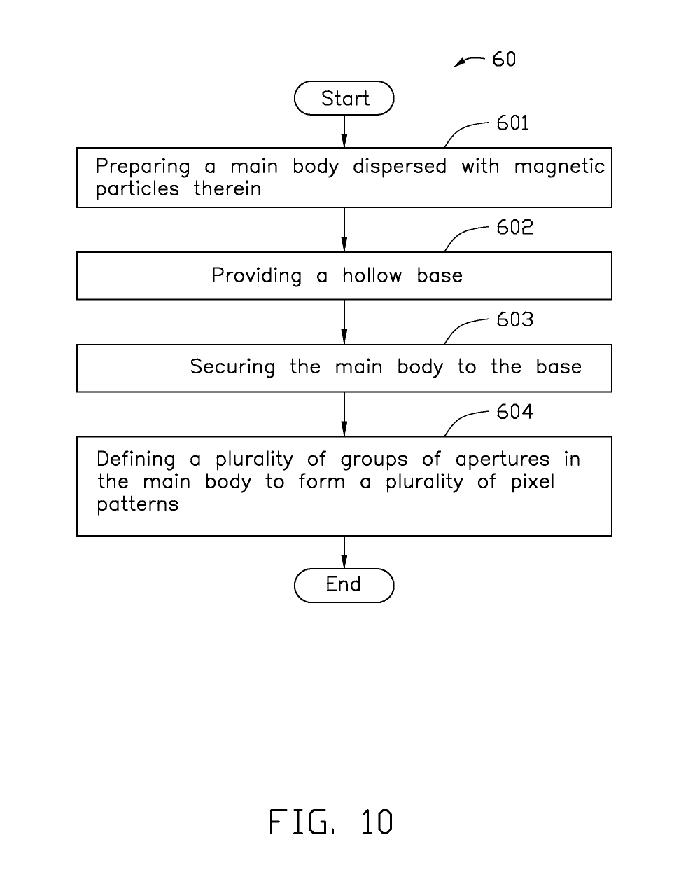

Referring to FIG. 10, a flowchart is presented in accordance with an example embodiment. The example method 60 is provided by way of example, as there are a variety of ways to carry out the method. The method 60 described below can be carried out to manufacture the evaporation mask 200 illustrated in FIGS. 8 and 9. Each block shown in FIG. 10 represents one or more processes, methods or subroutines, carried out in the example method 60. Furthermore, the illustrated order of blocks is illustrative only and the order of the blocks can change according to the present disclosure. Additional blocks can be added or fewer blocks may be utilized, without departing from this disclosure. The example method 60 can begin at block 601.

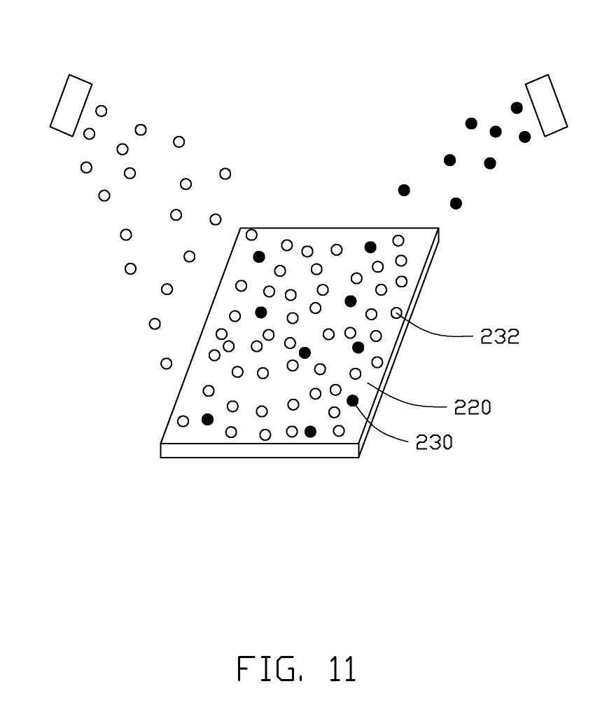

At block 601, also referring to FIG. 11, magnetic particles 230 and resin particles 232 are mixed together and then heat pressed to form the main body 220. In this embodiment, the resin particles 232 are polyimide resin particles.

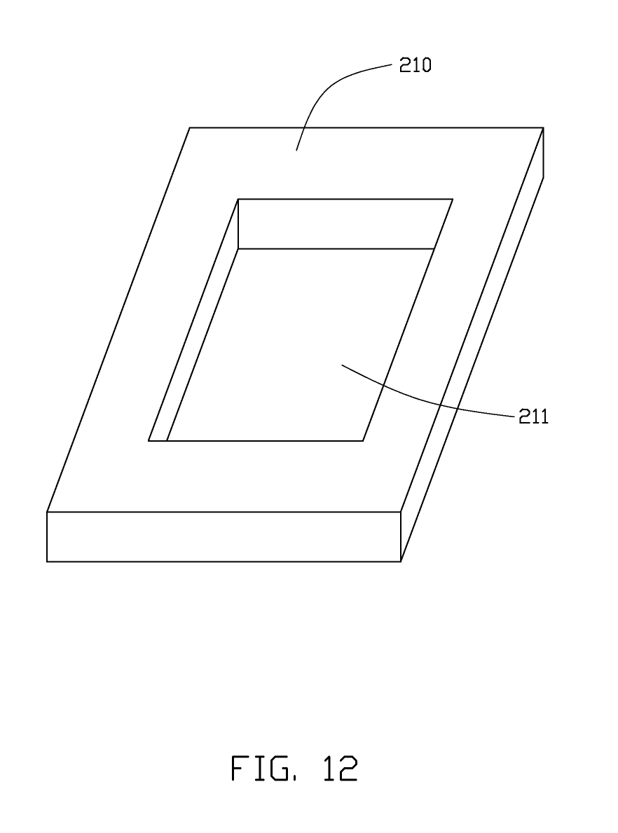

At block 602, also referring to FIG. 12, the base 210 is provided which is a hollow rectangle defining the central rectangular opening 211 whereby the base 210 has a configuration of a rectangular frame.

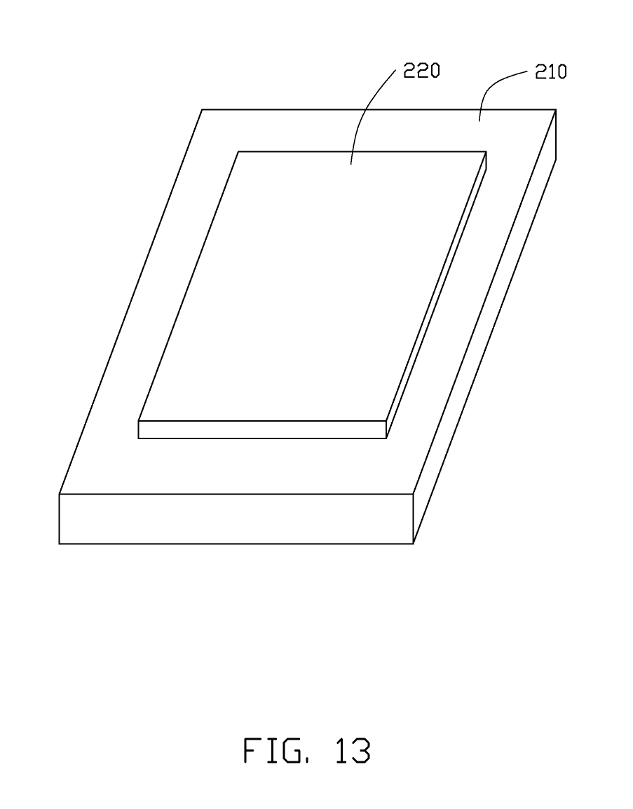

At block 603, also referring to FIG. 13, the main body 220 is adhered to a center of a top face of the base 210 around the opening 211 to cover the opening 211 of the base 210.

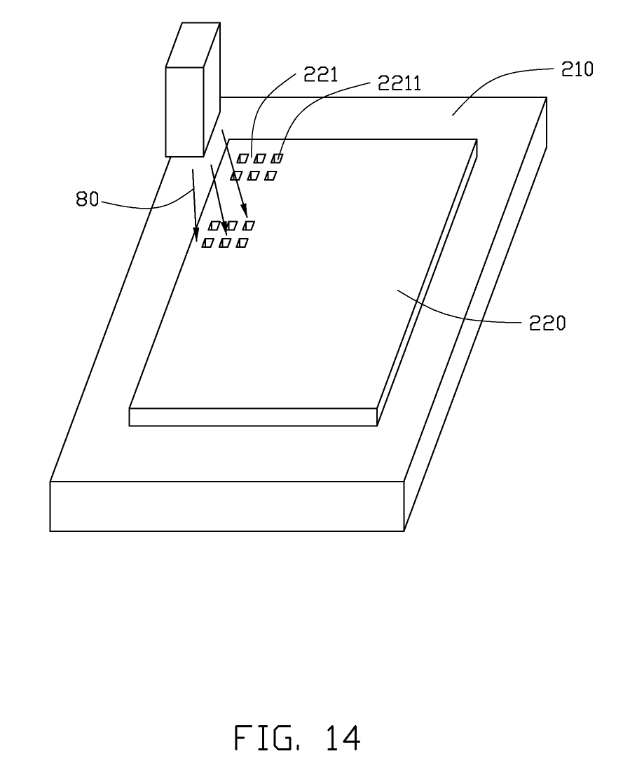

At block 604, also referring to FIG. 14, the main body 120 is processed to form the plurality of pixel patterns 221 by using laser beams 80 to form the plurality of groups of apertures 1211 in the main body 220. Accordingly the evaporation mask 200 in accordance with the second embodiment of the present disclosure is obtained. A display substrate which is subjected to vapor deposition by using the evaporation mask 200 can obtain a plurality of pixel patterns thereon. By severing the display substrate according the pixel patterns, a plurality of display sub-substrates each of which can be used for constituting a display screen can be obtained.

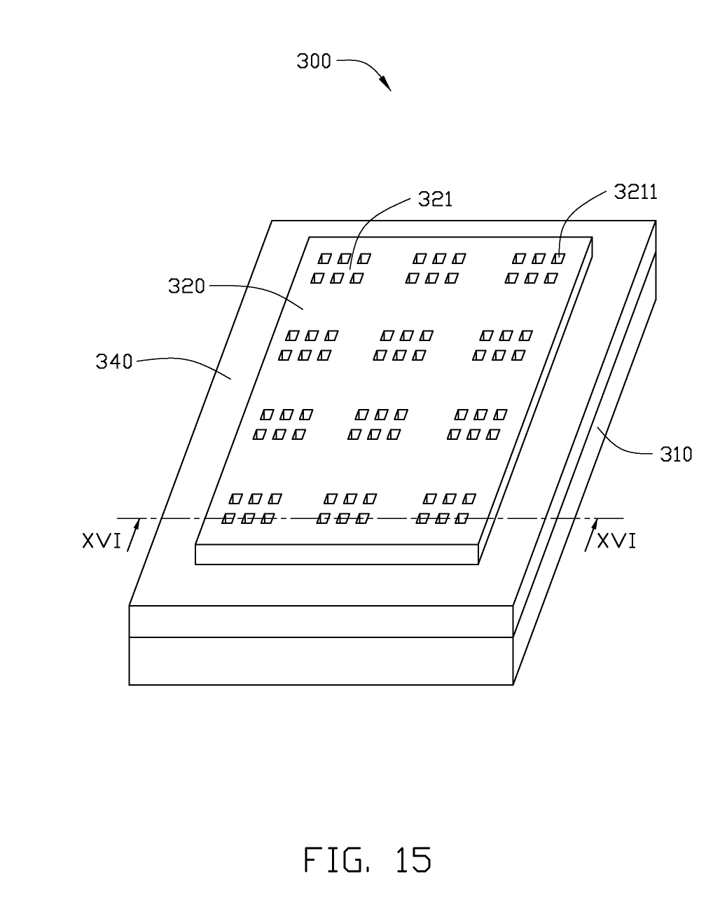

Referring to FIG. 15, an evaporation mask 300 in accordance with a third embodiment of the present disclosure is shown. The evaporation mask 300 includes a base 310, a middle plate 340 over the base 310 and a main body 320 over the middle plate 340. Each of the base 320, the middle plate 340 and the base 310 is substantially rectangular in shape. The base 310 and the middle plate 340 have substantially the same size, while the main body 310 has a smaller size and is located over a center of the middle plate 340. The main body 340 defines a plurality of groups of apertures 3211 therein to define a plurality of pixel patterns 321 each corresponding to a group of apertures 3211 which is arranged in a rectangular array.

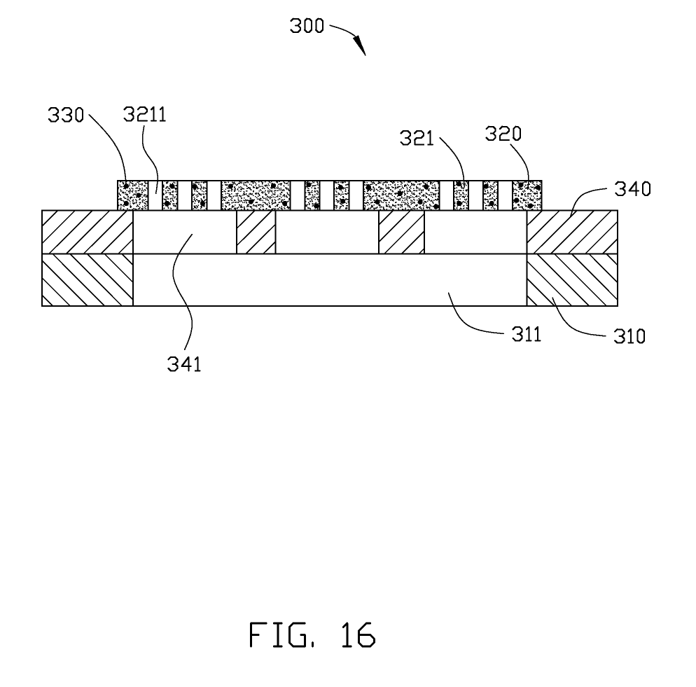

Referring to FIG. 16, the base 310 defines a central, rectangular opening 311 therethrough. The middle plate 340 defines a plurality of rectangular holes 341 communicating with the rectangular opening 311. The main body 320 is located over a top face of the middle plate 340 to cover the holes 341 and the opening 311, wherein all of the apertures 3211 of the main body 320 communicate with the holes 341 and the opening 311. A plurality of magnetic particles 330 is dispersed in the main body 320.

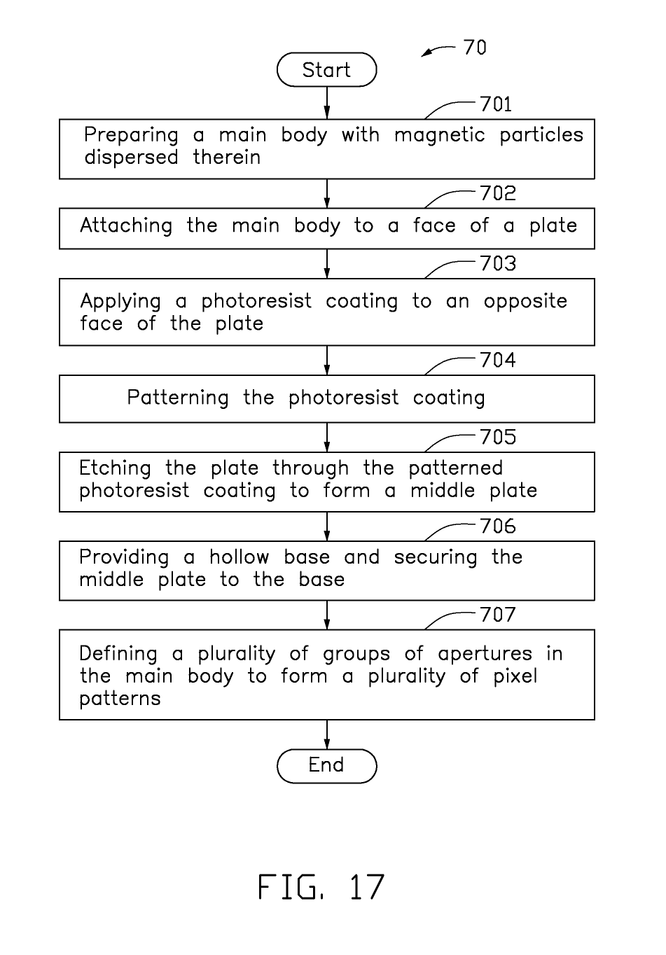

Referring to FIG. 17, a flowchart is presented in accordance with an example embodiment. The example method 70 is provided by way of example, as there are a variety of ways to carry out the method. The method 70 described below can be carried out to manufacture the evaporation mask 300 illustrated in FIGS. 15 and 16. Each block shown in FIG. 17 represents one or more processes, methods or subroutines, carried out in the example method 70. Furthermore, the illustrated order of blocks is illustrative only and the order of the blocks can change according to the present disclosure. Additional blocks can be added or fewer blocks may be utilized, without departing from this disclosure. The example method 70 can begin at block 701.

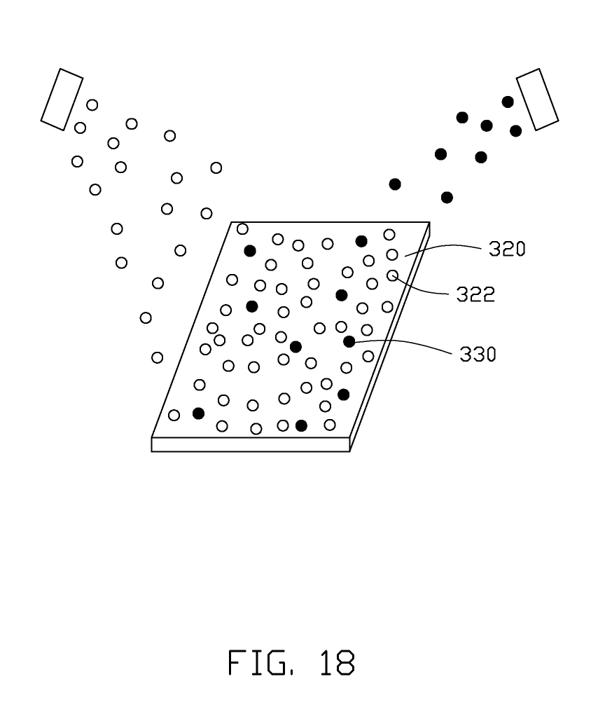

At block 701, also referring to FIG. 18, magnetic particles 330 and resin particles 322 are mixed together and then heat pressed to form the main body 320. In this embodiment, the resin particles 322 are polyimide resin particles.

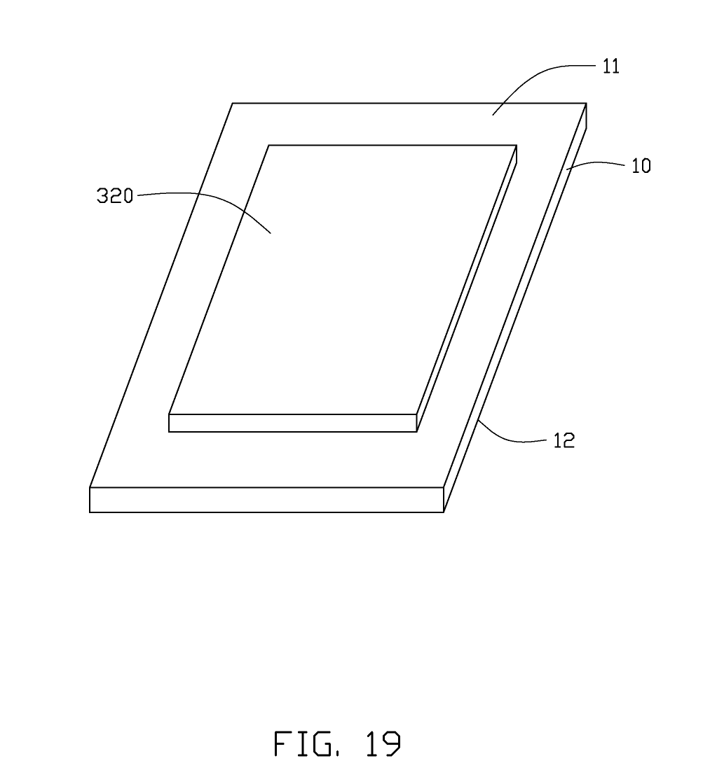

At block 702, also referring to FIG. 19, a plate 10 for forming the middle plate 340 is provided. The main body 320 is adhered to a top face 11 of the plate 10, which has a bottom face 12 opposite the top face 11. The plate 10 can be made of glass or magnetic metal such as Invar. In this embodiment, the plate is made of Invar.

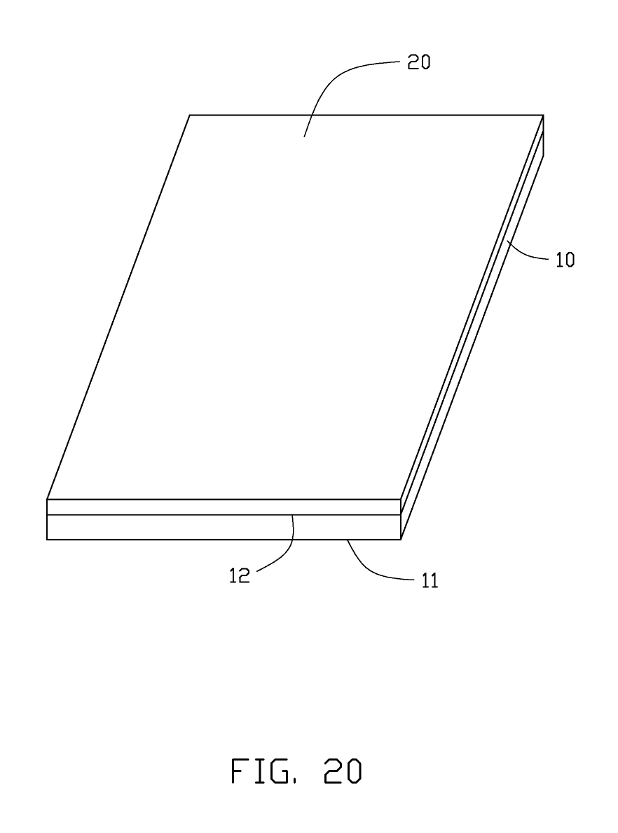

At block 703, also referring to FIG. 20, the plate 10 together with the main body 320 is inverted. Then a photoresist coating 20 is applied to the bottom face 12 of the plate 10.

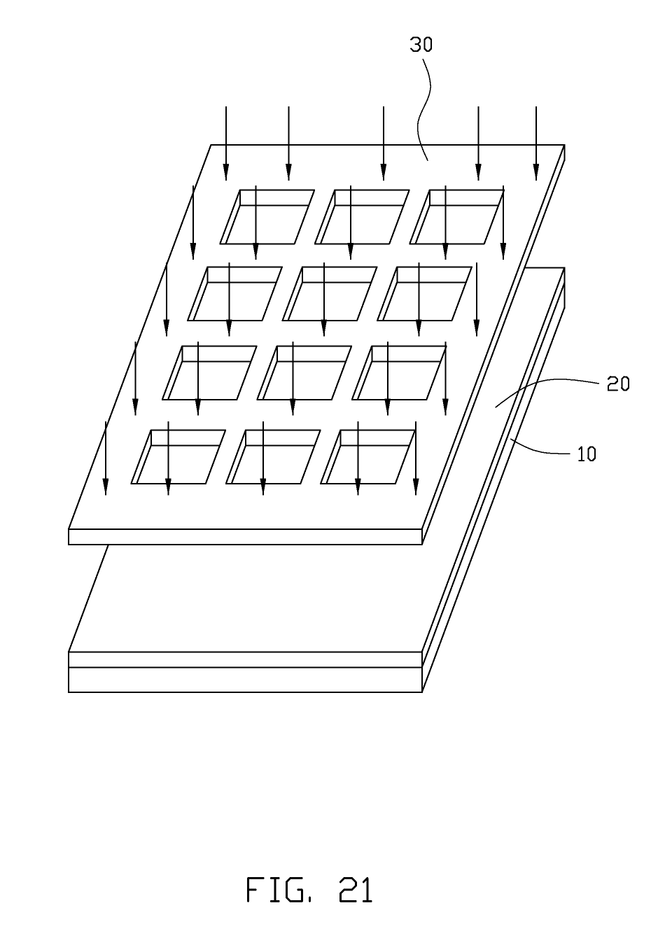

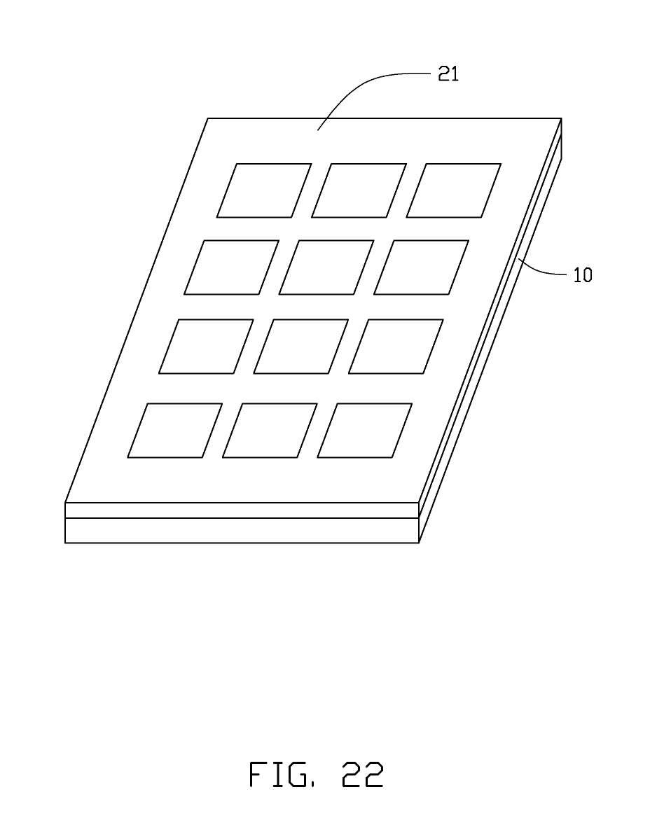

At block 704, also referring to FIG. 21, a photo mask 30 is brought over the photoresist coating 20 and a light irradiation is applied to the photoresist coating 20 through the photo mask 30 as indicated by arrows in FIG. 21. Accordingly, the photoresist coating 21 becomes a patterned coating 21, as shown in FIG. 22.

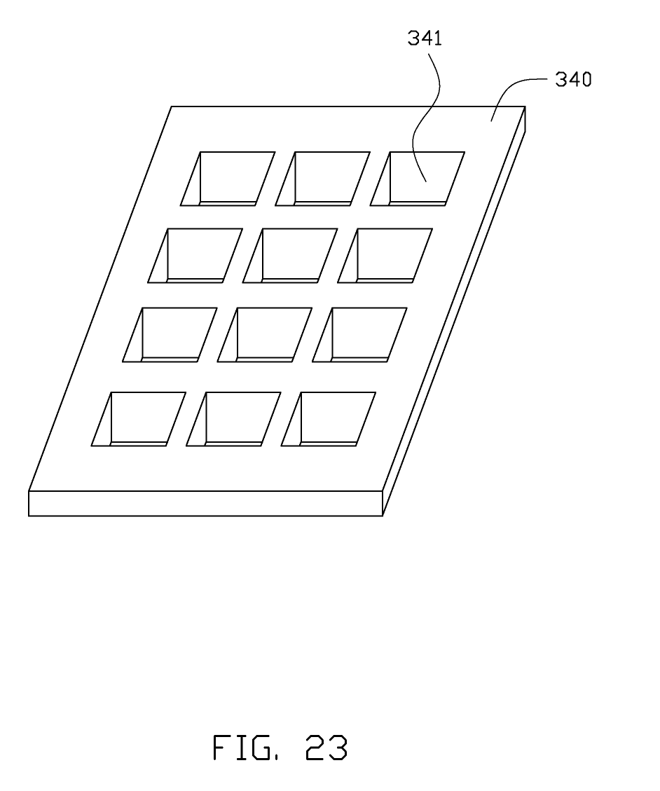

At block 705, also referring to FIG. 23, an etching is processed to the plate 10 to define the plurality of holes 341 therethrough to thereby obtain the middle plate 340.

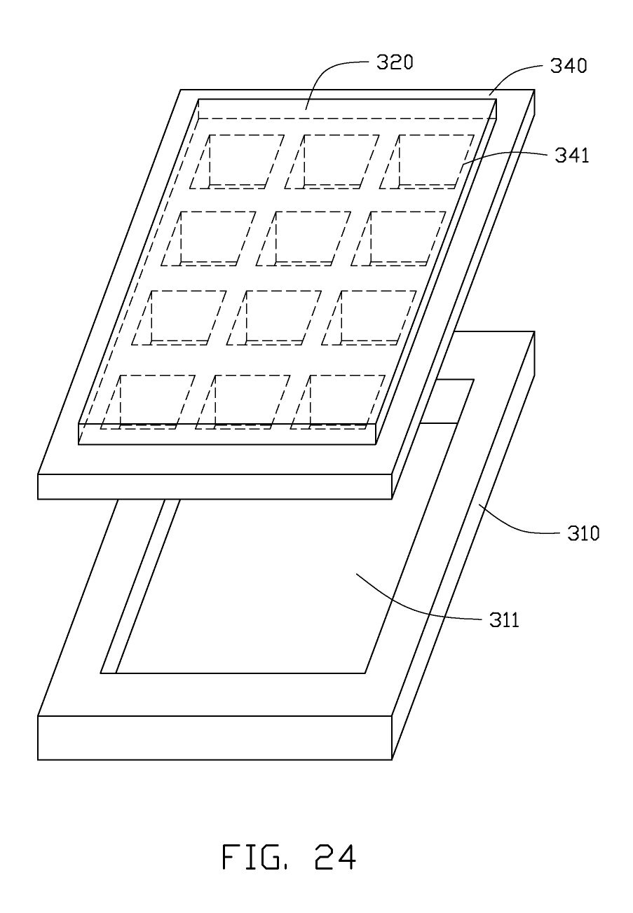

At block 706, also referring to FIG. 24, the base 310 is provided, which defines the central rectangular opening 311 therein. The middle plate 340 is inverted again to have main body 320 at an upper side thereof. A bottom face of the middle plate 340 is adhered or soldered to the base 310.

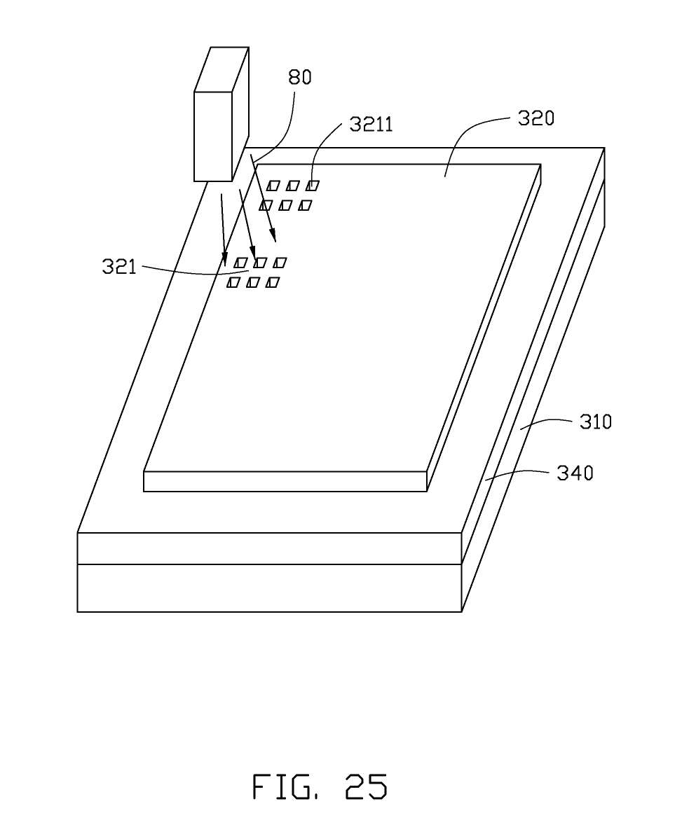

At block 707, also referring to FIG. 25, laser beams 80 are applied to the main body 320 to define the plurality of groups of apertures 3211 therein to form the plurality of pixel patterns 321. Thus, the evaporation mask 300 in accordance with the third embodiment of the present disclosure is obtained.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in particular the matters of shape, size and arrangement of parts within the principles of the present disclosure, up to and including the full extent established by the broad general meaning of the terms used in the claims.

What is claimed is:

1. An evaporation mask for vapor deposition to form pixels on a display substrate, comprising:
a main body defining at least one group of apertures therein to form at least one pixel pattern, the main body being made of resin and comprising magnetic particles dispersed in the resin; and
a base defining an opening therein, the main body being mounted on the base, the at least one group of apertures being in communication with the opening.

2. The evaporation mask of claim 1, further comprising a middle plate sandwiched between the main body and the base, the middle plate defining a plurality of holes in communication with the opening, the main body defining a plurality of groups of apertures to form a plurality of pixel patterns, each group of apertures being in communication with a corresponding hole.

3. The evaporation mask of claim 1, wherein the resin is selected from the group consisting of polyimide, polyethylene naphthalate, polyethylene terephthalate, and polysulfone.

4. The evaporation mask of claim 3, wherein the resin is polyimide resin.

5. The evaporation mask of claim 3, wherein the magnetic particles each having a diameter not larger than 1 μm.

6. The evaporation mask of claim 5, wherein the apertures each have a shape of a square.

7. The evaporation mask of claim 6, wherein the base is made of magnetic metal.

8. The evaporation mask of claim 7, wherein the base is made of Invar.

9. A method for forming an evaporation mask for vapor deposition, comprising:
mixing resin particles and magnetic particles together to obtain a mixture;
heat pressing the mixture to obtain a main body having a configuration of a thin plat; and
forming at least one group of apertures through the main body to form at least one pixel pattern in the main body.

10. The method of claim 9, wherein the resin is polyimide resin.

11. The method of claim 9, wherein the magnetic particles each have a diameter not larger than 1 μm.

12. The method of claim 9, further comprising providing a base defining an opening, and securing the main body onto the base to cover the opening, wherein the at least one group of apertures communicates with the opening.

13. The method of claim 12, wherein the resin is polyimide resin, and the base is made of Invar.

14. The method of claim 12, wherein the step of securing the main body onto the base is performed before the step of forming the at least one group of apertures.

15. The method of claim 14, wherein the step of forming at least one group of apertures forms a plurality of groups of apertures in the main body to define a plurality of pixel patterns each including a corresponding group of apertures.

16. The method of claim 9, further comprising:
providing a plate and securing the main body onto a top face of the plate;
applying a photoresist coating on a bottom face of the plate;
exposing the photoresist coating to light irradiation through a mask to form a pattern;
etching the plate through the pattern to obtain a plurality of holes in the plate to obtain a middle plate;
providing a base defining a central hole; and
securing a bottom face of the middle plate to the base;
wherein the step of forming at least one group of apertures forms a plurality of groups of apertures in the main body to form a plurality of pixel patterns each including a corresponding group of apertures.

17. The method of claim 16, wherein the step of forming a plurality of groups of apertures is performed after the step of securing the middle plate to the base.

18. The method of claim 16, wherein each of the base and the plate is made of magnetic metal.

19. The method of claim 16, wherein the magnetic particles each have a diameter not larger than 1 μm.
